(19) United States
(12) Patent Application Publication
(10) Pub. No.: US 2025/0127035 A1
(43) Pub. Date: Apr. 17, 2025

(54) PREPARATION METHOD FOR PEROVSKITE THICK FILM AND RADIATION DETECTOR COMPRISING PEROVSKITE THICK FILM

(71) Applicant: Industrial Technology Research Institute, Hsinchu (TW)

(72) Inventors: Kuo-Wei HUANG, Hsinchu (TW); Jen-An CHEN, Hsinchu (TW)

(73) Assignee: Industrial Technology Research Institute, Hsinchu (TW)

(21) Appl. No.: 18/528,351

(22) Filed: Dec. 4, 2023

(30) Foreign Application Priority Data
Oct. 17, 2023 (TW) 112139683

(51) Int. Cl. H10K 85/50; G01T 1/24; H10K 39/36; H10K 71/15; H10K 71/40

(52) U.S. Cl. CPC H10K 85/50; H10K 39/36; H10K 71/15; H10K 71/40; G01T 1/24

(57) ABSTRACT

Provided is a radiation detector, comprising a substrate, a pixel array formed on the substrate, a perovskite thick film formed on the pixel array and having nanosheet structure, and a readout circuit electrically connected to the pixel array, wherein the perovskite thick film comprises CsPbBrₘI₃₋ₘ or FAPbBrₘI₃₋ₘ, 0≤m≤3, a surfactant and a ligand. A preparation method for a perovskite thick film is also provided.

### CROSS-REFERENCE TO RELATED APPLICATIONS

This application claims priority to Taiwan Application Serial No. 112139683, filed on Oct. 17, 2023. The entirety of the application is hereby incorporated by reference herein and made a part of this application.

### TECHNICAL FIELD

The present disclosure relates to a perovskite thick film, the preparation method thereof, and a radiation detector comprising the perovskite thick film.

### BACKGROUND

The radiation detector (such as an X-ray detector) can be found in various important fields, including medical imaging, safety monitoring, substance analysis, etc. It has been discovered in previous studies that a perovskite material has unique advantages of a high radiation absorption coefficient, a high carrier mobility-lifespan product (about 10⁻² cm²V⁻¹) and the like, and it is therefore considered to be one of the novel radiation detector materials, which has high sensitivity and can yield data at a low radiation dose, thereby reducing exposure dose during operation.

Perovskite should be thick enough to achieve sufficient absorption of X ray, since X-ray has a very strong penetrability. However, a perovskite film prepared by conventional manners, such as spin coating, blade coating, etc., typically has an insufficient thickness, causing difficulty in achieving effective absorption of X-ray.

Additionally, in most of the current studies using perovskite as a radiation detector material, a perovskite scintillator with a quantum dot structure is commonly used, whereas this type does not have good enough thermal resistance and humidity resistance under the atmospheric environment and thus shows a less ideal stability. If a ligand is used in an increased amount to improve stability, the radioluminescence intensity will be reduced unfavorably.

On the other hand, there is also an increasing need for large-area detection, but the primary issue of uniformity over an increased area needs to be solved.

### SUMMARY

The embodiment provides a radiation detector, comprising: a substrate; a pixel array formed on the substrate; a perovskite thick film formed on the pixel array and having a nanosheet structure; and a readout circuit electrically connected to the pixel array, wherein the perovskite thick film comprises CsPbBrₘI₃₋ₘ or FAPbBrₘI₃₋ₘ with 0≤m≤3, wherein the perovskite thick film comprises a surfactant and a ligand.

The embodiment also provides a method of preparing the perovskite thick film, comprising:
a) providing a perovskite precursor solution; b) spraying the perovskite precursor solution on a substrate to form a perovskite film; c) repeating the step b) to form a perovskite thick film; and d) subjecting the perovskite thick film to an annealing treatment to obtain a perovskite thick film having a nanosheet structure.

### BRIEF DESCRIPTION OF THE DRAWINGS

FIGS. 1A-1D are SEM images showing the perovskite precursor solutions of Example 1, which are not subjected to the ultrasonic vibration pretreatment or subjected to the ultrasonic vibration pretreatment for 1, 5, and 10 minutes, respectively.

FIGS. 2A-2D are an SEM image in top view, an SEM image of a cross-section, an SEM image of a cross-section, and a TEM image of the perovskite thick film prepared by ultrasonic spraying in Example 2, respectively.

FIGS. 3A-3C are an SEM image in top view, an SEM image of a cross-section, and a TEM image of the perovskite film prepared by drop casting in Example 2, respectively.

FIG. 4 is a X-ray diffraction (XRD) pattern of respective perovskite films of Example 3.

FIG. 5 is a graph showing the radioluminescence (RL) intensities of respective perovskite films of Example 4.

FIG. 6 is a graph showing the thickness-photoluminescence quantum yield (PLQY) relationship and the thickness-RL intensity relationship of respective perovskite films of Example 4.

FIG. 7 is a graph showing RL of the large size perovskite thick film prepared by ultrasonic spraying in Example 4.

FIGS. 8A and 8B are graphs showing modulation transfer functions (MTF) back-calculated from CCD camera images of the drop-casting perovskite film and ultrasonic spraying perovskite thick film of Example 4, respectively.

FIG. 9 shows optical micrographs and interface analysis of the ultrasonic spraying perovskite thick films of Example 5.

FIG. 10 shows the distribution of the photoluminescence (PL) wavelengths and full widths at half maximum of the ultrasonic spraying perovskite thick films of Example 5 and a commercially available QD material.

FIG. 11 shows the distribution of the PL wavelengths and the full widths at half maximum of the ultrasonic spraying perovskite thick films comprising various surfactants of Example 6 and a commercially available QD material.

FIGS. 12A and 12B are graphs showing RL of 9 positions taken from the ultrasonic spraying perovskite thick films on a hard substrate and a soft substrate of Example 7, respectively.

FIG. 13 is a graph showing RL of the ultrasonic spraying perovskite thick films comprising various ligands of Example 8.

FIGS. 14A and 14B are TEM images of the ultrasonic spraying perovskite thick films comprising various ligands of Example 8, respectively.

FIGS. 15A-15C are TEM images of the ultrasonic spraying CsPbBr₃ thick film of Example 9, and the ultrasonic spraying CsPbI₃ thick film of Example 9, and a commercially available QD CsPbBr₃ thick film.

FIG. 16 is a graph showing RL of the ultrasonic spraying CsPbBr₃ thick film of Example 9 and a commercially available QD CsPbBr₃ thick film.

FIG. 17 is a graph showing RL of the ultrasonic spraying CsPbI₃ thick film of Example 9.

FIGS. 18A and 18B is graphs showing RL of 9 positions taken from a commercially available quantum dot perovskite film and the ultrasonic spraying perovskite thick film on a soft substrate of Example 10, respectively.

FIG. 19 is a graph showing RL of a commercially available quantum dot perovskite film and the ultrasonic spraying perovskite thick films on a hard substrate and a soft substrate of Example 10.

FIG. 20A is a photograph showing the application example of the ultrasonic spraying perovskite thick film of Example 11 in the field of medical detection; FIGS. 20B-20C are photographs showing the application examples in the field of industrial destructive testing.

FIG. 21 is a structural schematic diagram of the radiation detector of Example 11.

### DETAILED DESCRIPTION

The detailed description of the present disclosure is illustrated by specific embodiments, and a person having ordinary skill in the art can readily appreciate the scope and efficacy of the present disclosure based on the content recorded herein. However, the embodiments recorded herein are not intended to limit the present disclosure. The technical features or solutions listed can be combined with one another. The present disclosure can be implemented or applied by other different embodiments. Details recorded herein may be altered or modified differently according to different viewpoints and applications without departing from the present disclosure.

Unless stated otherwise, “comprising,” “containing,” or “having” particular elements used herein means that other elements such as units, components, structures, regions, parts, devices, systems, steps, and connection relationships can be also included rather than excluded.

Unless expressly stated otherwise, the singular forms “a,” “an,” and “the” used herein also include the plural forms, and the “or” and “and/or” used herein can be used interchangeably.

The numeric ranges described herein are inclusive and can be combined, and any value falling within the numeric ranges described herein can be used as the upper or lower limit to derive a subrange; for example, a numeric range of “520 nm to 600 nm” should be understood to include any subrange from a lower limit of 520 nm to an upper limit of 600 nm, e.g., subranges of 520 nm to 590 nm, 530 nm to 600 nm, and 530 nm to 590 nm and so on. A value should be considered to be included in the range of the present disclosure if the value falls within the numeric ranges described herein (e.g., 550 nm falls within the numeric range from 520 nm to 600 nm).

The present disclosure provides a perovskite thick film and a method of preparing the perovskite thick film. A method of preparing the perovskite thick film comprises:
a) providing a perovskite precursor solution;
b) spraying the perovskite precursor solution on a substrate to form a perovskite film;
c) repeating the step b) to form a perovskite thick film; and
d) subjecting the perovskite thick film to annealing treatment to obtain a perovskite thick film having a nanosheet structure.

In some embodiments, the perovskite precursor solution comprises a perovskite precursor salt, a surfactant, a solvent, and a ligand.

In some embodiments, the perovskite precursor salt comprises CsPbBrₘI₃₋ₘ or FAPbBrₘI₃₋ₘ with 0≤m≤3, for example, CsPbBr₃, CsPbBr_{1.5}I_{1.5}, FAPbBr₃, and FAPbBr_{1.5}I_{1.5}.

In some embodiments, the ligand is a carboxylic acid and a primary amine both having more than 8 carbon atoms. In some embodiments, said more than 8 carbon atoms are, for example, 8 to 12. For example, the carboxylic acid may be octanoic acid, nonanoic acid, decanoic acid, undecanoic acid, and dodecanoic acid; and the primary amine may be octyl amine, nonyl amine, decyl amine, undecyl amine, and dodecyl amine. In other embodiments, the ligand is a combination of octanoic acid and octyl amine, or a combination of decanoic acid and decyl amine.

In some embodiments, the surfactant is a non-ionic surfactant. In other embodiments, the surfactant is at least one selected from the group consisting of Tween 20, Tween 40, Tween 60, Tween 65 and Tween 80.

The surfactant herein functions to promote self-assembling when a perovskite precursor solution is sprayed into droplets and dropped on a substrate, thereby decreasing the surface tension affected by the capillary action and allowing the perovskite thick film to have a nanosheet structure and a high uniformity.

In some embodiments, the surfactant is present in the perovskite precursor solution at an amount of 0.001 wt % to 0.2 wt %, 0.005 wt % to 0.05 wt %, e.g., 0.005, 0.01, 0.02, 0.015, 0.02, 0.025, 0.03, 0.035, 0.04, 0.045, 0.05, 0.06, 0.07, 0.08, 0.1, and 0.2 wt %.

In further embodiments, the surfactant is 0.005 wt % to 0.05 wt % of Tween 60.

In some embodiments, the solvent may be at least one selected from the group consisting of toluene, dimethyl sulfoxide (DMSO), N,N-dimethylformamide (DMF), fobutyrolactone (GBL), N,N-dimethylacetamide (DMAC), ethanol, isopropanol, n-propanol, n-butanol, isobutanol, and n-hexane.

In some embodiments, in the perovskite precursor solution, the volume ratio of the surfactant:the ligand:the solvent is 0.8-1.2:0.8-1.2:1.

In some embodiments, the spraying used in the step b) is an ultrasonic spraying. In other embodiments, the ultrasonic powder is 1 W to 3 W, e.g., 1, 1.5, 2, 2.5, and 3 W; and the ejection rate is 0.1 mL/min to 3 mL/min, e.g., 0.1, 0.2, 0.3, 0.4, 0.5, 0.6, 0.7, 0.8, 0.9, 1, 1.5, 2, 2.5, and 3 mL/min.

In some embodiments, during the spraying in the step b), a nozzle moves from an initial position to spray the perovskite precursor solution on each position on the surface of the substrate, thereafter, the nozzle returns to the initial position and starts again spraying the perovskite precursor solution on each position of the substrate, to perform the repeated spraying of the step c), thereby preparing a perovskite thick film. In other embodiments, the nozzle moves at a speed of 1 mm/s to 50 mm/s, e.g., 1, 2, 3, 4, 5, 6, 7, 8, 9, 10, 15, 20, 25, 30, 35, 40, 45, and 50 mm/s.

In some embodiments, the film-forming is performed at a room temperature (20° C. to 25° C.) after the perovskite precursor solution is sprayed on the substrate. In other embodiments, when the perovskite precursor solution is sprayed on the substrate, the substrate is heated, i.e., the method of the present disclosure can further comprises step e): heating the perovskite film or the perovskite thick film. In further embodiments, the heating is at a temperature of 25° C. to 200° C., e.g., 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, and 200° C. In other embodiments, the heating is at a temperature of, e.g., 30° C. to 200° C., 40° C. to 180° C., 50° C. to 160° C., and 60° C. to 140° C.

In some embodiments, the method of the present disclosure can further comprises, between the step a) and the step b), step f): subjecting the perovskite precursor solution to a vibration pretreatment. In other embodiments, the vibration pretreatment is an ultrasonic vibration pretreatment at an ultrasonic vibration power of 100 W to 200 W, e.g., 100, 110, 120, 130, 140, 150, 160, 170, 180, 190, and 200 W. In other embodiments, the ultrasonic vibration power may be, e.g., 110 W to 190 W, 120 W to 180 W, 130 W to 170 W, and 140 W to 160 W. The pretreatment is performed for 1 to 10 minutes, e.g., 1, 2, 3, 4, 5, 6, 7, 8, 9, and 10 minutes. In further embodiments, the step b) is performed within 1 hour after performing the step f), which subjects the perovskite precursor solution to a vibration pretreatment.

The perovskite thick film of the present disclosure can be prepared according to the present disclosure, the method described above, however, the perovskite thick film of the present disclosure can also be prepared by methods other than that described above.

The present disclosure provides a perovskite thick film having a nanosheet structure and comprising perovskite, a surfactant and a ligand.

In some embodiments, the surfactant is a non-ionic surfactant. In other embodiments, the surfactant is polysorbate (Tween), poloxamer, fatty alcohol, Triton, and octyl phenol ethoxide (IGEPAL), and is preferably at least one selected from the group consisting of Tween 20, Tween 40, Tween 60, Tween 65, and Tween 80. In further embodiments, the surfactant is Tween 60.

In some embodiments, the X-ray diffraction (XRD) pattern of the perovskite thick film comprises a (100) signal at 3.9±0.3°, a (200) signal at 7.6±0.3° and a (220) signal at 11.4±0.3°.

In some embodiments, the perovskite thick film has a thickness of 60 μm to 1000 μm, 80 μm to 900 μm, 90 μm to 800 μm, 100 μm to 700 μm, and 200 μm to 600 μm.

The present disclosure further provides a radiation detector, comprising a substrate, a pixel array formed on the substrate, a perovskite thick film formed on the pixel array and having a nanosheet structure, and a readout circuit electrically connected to the pixel array, wherein the perovskite thick film is the one described in the present disclosure, which will not be described again below.

In some embodiments, the perovskite thick film has a detecting surface with an area of 200 cm² to 2500 cm², e.g., 200, 400, 600, 800, 1000, 1200, 1400, 1600, 1800, 2000, 2200, 2400 or 2500 cm².

In some embodiments, the radiation detector is an indirect radiation detector. Upon irradiating a perovskite thick film, X-ray will be converted into a visible light and be collected by a TFT array, thus, the radiation dose can be obtained by processing and analyzing the visible light. The radiation detector further comprises a photoelectric transducer element, e.g., a switching diode, that can convert a visible light to an electric signal. Under the control of a control circuit, the electric signal is read out by a multiplexer, and the readout signal is processed with a back-end software for imaging.

In some embodiments, the radiation detector is an X-ray detector, a gamma ray detector, or an X-ray and gamma ray detector.

In some embodiments, the pixel array comprises a charge coupled device (CCD), a complementary metal oxide semiconductor (CMOS), a thin film transistor (TFT), indium gallium zinc oxide (IGZOs) or a photomultiplier tube (PMT).

In some embodiments, the material of the substrate is selected from the group consisting of glass, poly(ethylene terephthalate) (PET), polydimethylsiloxane (PDMS), aluminum, rubbers (e.g., ethylene propylene diene methylene rubbers, butadiene styrene rubbers, silicone rubbers), fluoropolymers (e.g., polytetrafluoroethylene, perfluoroalkoxy alkanes, ethylene-tetrafluoroethylene), optical fiber plates, silica (SiO₂), ceramics (e.g., silicon nitrate, silicon carbide, aluminum oxide, and boron carbide). In other embodiments, the material of the substrate is selected from PDMS, SiO₂, PET, and glass.

In some embodiments, the radiation detector has a radioluminescence (RL) wavelength between 520 nm and 600 nm, e.g., 520, 525, 530, 535, 540, 545, 550, 555, 557, 560, 565, 570, 575, 580, 585, 590, 595, and 600 nm; and the radiation detector has an RL with a full width at half maximum of 25 nm or less, e.g., 25, 24, 23, 22, 21, and 20 nm.

### EXAMPLES

Further details will be described in the present disclosure by referencing to following Examples which are in no way intended to limit the scope of the present disclosure.

### Example 1—Vibration Pretreatment

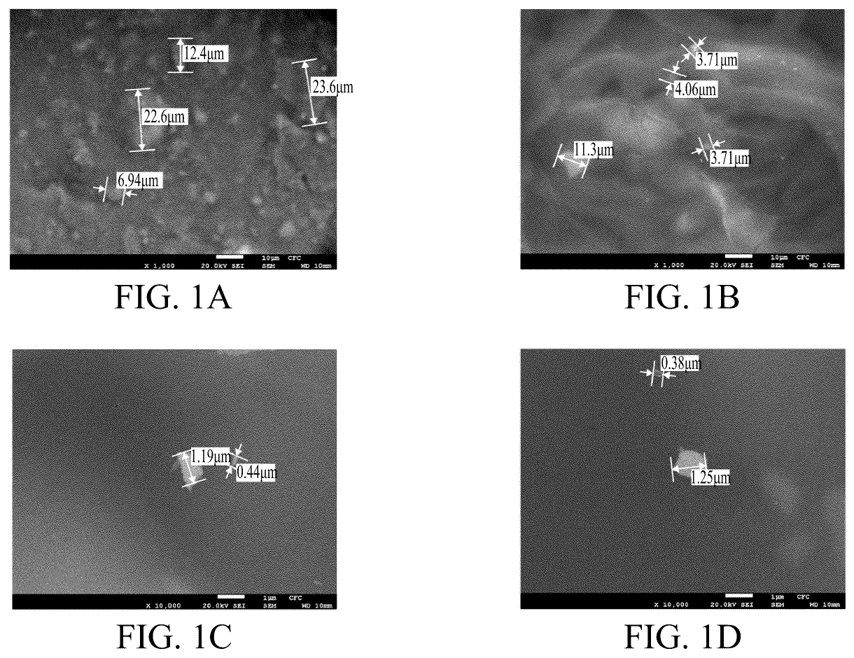

Firstly, 3.2 mM perovskite precursor solution was prepared by using 0.3071 g of caesium acetate (CsAc, 1.6 mmol) and 1.1477 g of lead bromide (PbBr₂, 3.2 mmol) as perovskite precursor salts, 0.02 wt % of Tween 60 as a surfactant, octanoic acid with octyl amine as ligands, and toluene as a solvent, wherein the volume ratio of toluene:octanoic acid:octyl amine was 1:1:1. Next, the perovskite precursor solution was subjected to an ultrasonic vibration pretreatment at a power of 150 W for 1, 5, or 10 minutes. The SEM images of the perovskite precursor solutions subjected to the ultrasonic vibration pretreatment were shown in FIGS. 1B, 1C, and 1D, respectively, and the SEM image of the perovskite precursor solution not subjected to the ultrasonic vibration pretreatment was shown in FIG. 1A. According to FIGS. 1A-1D, the ultrasonic vibration pretreatment ameliorated the aggregation of perovskite colloidal particles and improved dispersion. On the other hand, the problems of perovskite precursor precipitation and material clogging during the manufacture process can also be avoided due to the improved dispersion.

### Example 2—Ultrasonic Spraying

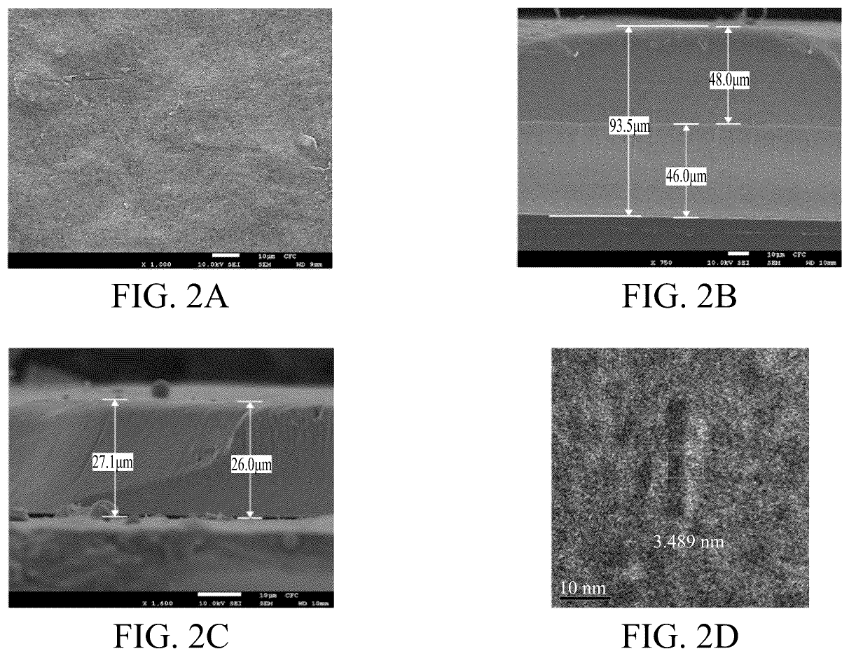

A perovskite precursor solution was prepared as Example 1, and then was applied to a substrate by ultrasonic spraying under an atmospheric environment. The substrate was heated through an underlying heating plate set at a temperature of 50° C., and the ultrasonic nozzle worked at a power of 3 W, an ejection rate of 0.5 mL/min, and a nozzle moving speed of 15 mm/s. The spraying was repeated after a layer had been sprayed to produce a perovskite thick film with a thickness of 93.5 μm, of which the SEM image in the top view was shown in FIG. 2A, the SEM images of the cross-section were shown in FIGS. 2B and 2C, and the TEM image was shown in FIG. 2D.

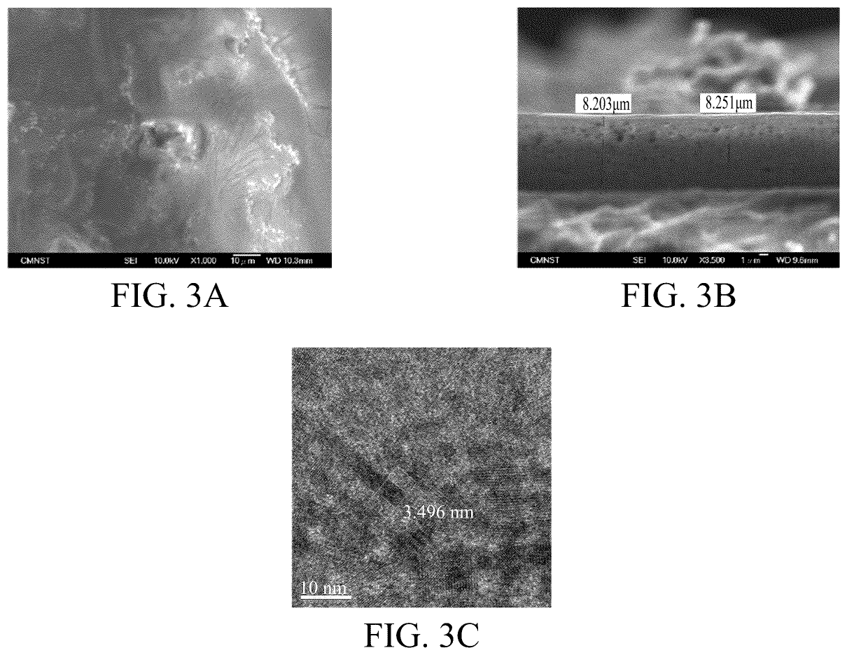

For comparison, a perovskite precursor solution was prepared in the same manner as aforementioned but was applied to a substrate by drop casting to produce a perovskite film, of which the SEM image in the top view was shown in FIG. 3A, the SEM image of the cross-section was shown in FIG. 3B, and the TEM image was shown in FIG. 3C.

According to the ultrasonic spraying perovskite thick film shown in FIGS. 2A-2D and the drop-casting perovskite film shown in FIGS. 3A-3C, it can be concluded that the ultrasonic spraying employed in the present application effectively ameliorates the problem of micron-scale pinholes occurring in the film, and also enables the production of vertically oriented micron-scaled thick films.

### Example 3—X-Ray Diffraction (XRD)

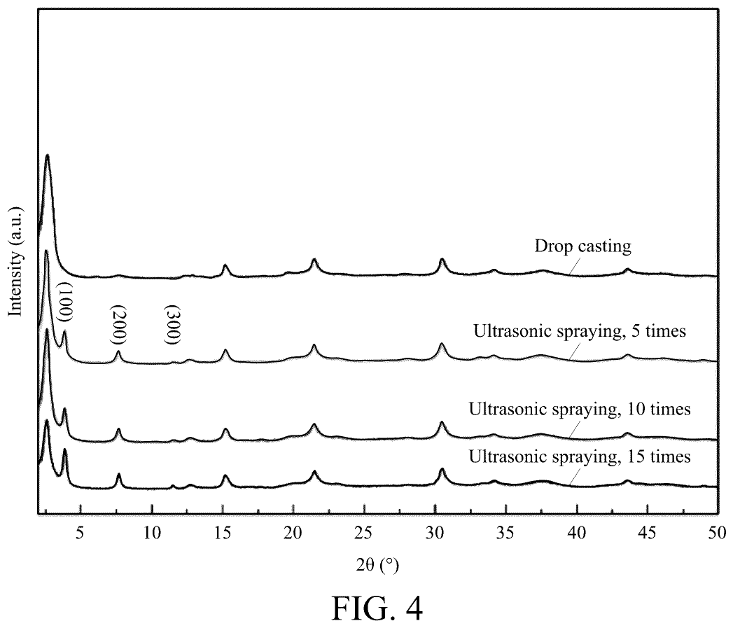

One drop-casting perovskite film and three ultrasonic spraying perovskite thick films were prepared as in Example 2, wherein the three ultrasonic spraying perovskite thick films were prepared by repeating the ultrasonic spraying step for 5, 10 or 15 times, respectively. The XRD patterns of each of the films described above were shown in FIG. 4. It can be seen that (100), (200), and (300) signals occur in the XRD patterns of the ultrasonic spraying perovskite thick films, indicating that the perovskite thick film prepared by the ultrasonic spraying exhibited a highly ordered superstructure. However, these signals do not exist in the XRD pattern of the drop-casting perovskite film or are very weak, i.e., the film had a relatively lower ordered molecular arrangement.

### Example 4—Radioluminescence (RL) Wavelength, Intensity and Photoluminescence Quantum Yield (PLQY)

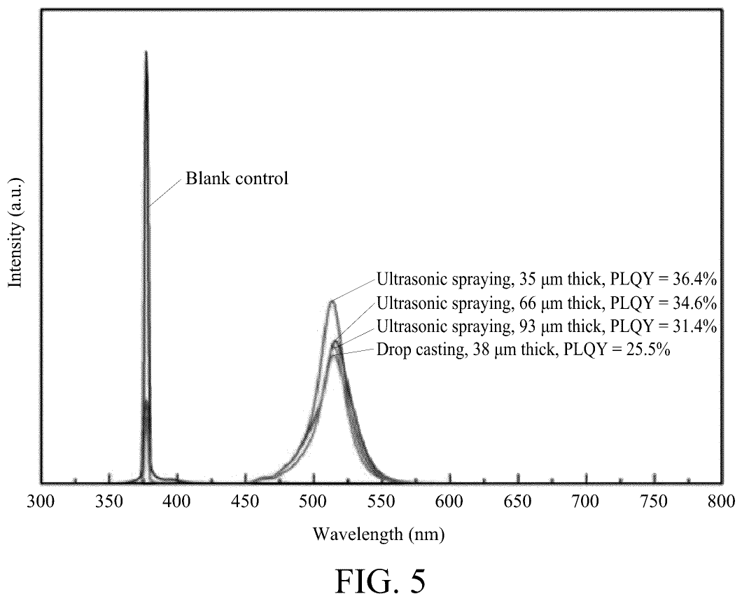

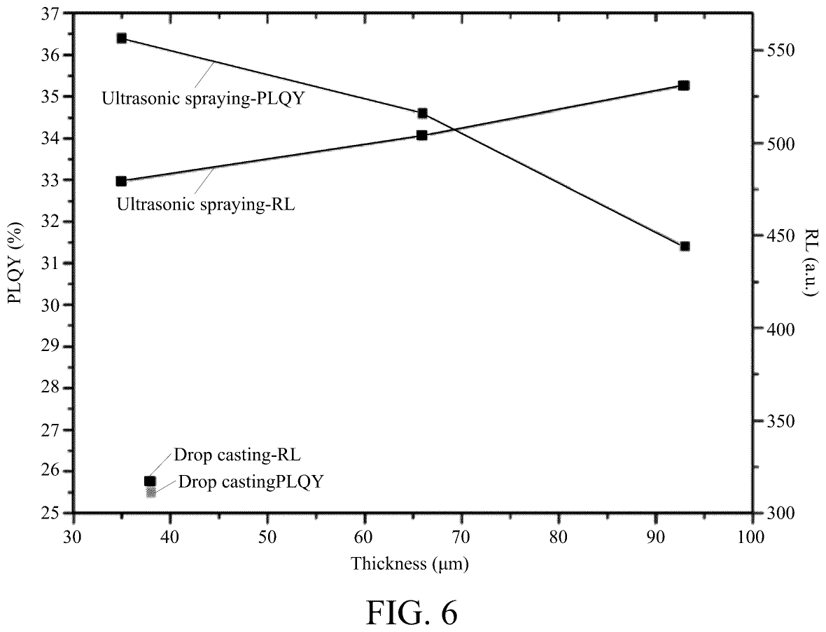

A drop-casting perovskite film with a thickness of 38 μm and ultrasonic spraying perovskite thick films with thickness of 35 μm, 66 μm and 93 μm (by controlling repeating times of ultrasonic spraying) were prepared as in Example 2. Each of the films were irradiated with X-ray (Model My Vet X500 X-ray: 0 kVp, 5 mA, purchased from Woorien, the same below), and the RL intensities and PLQYs generated by the films were recorded, as shown in FIG. 5 and FIG. 6. It can be seen that the ultrasonic spraying perovskite thick films had a PLQY which decreased slightly as the thickness increased but still higher than the PLQY of the drop-casting perovskite film. In addition, the trend of decreasing PLQY with increasing thickness of the ultrasonic spraying perovskite thick film seems to be caused by the self-absorption of the perovskite thick film. On the other hand, the RL intensity of the ultrasonic spraying perovskite thick films was also higher than that of the drop-casting perovskite film. Additionally, the trend of increasing RL intensity with increasing thickness of the ultrasonic spraying perovskite thick film seems to be caused by the enhanced ability of blocking high-energy electrons of the perovskite thick film.

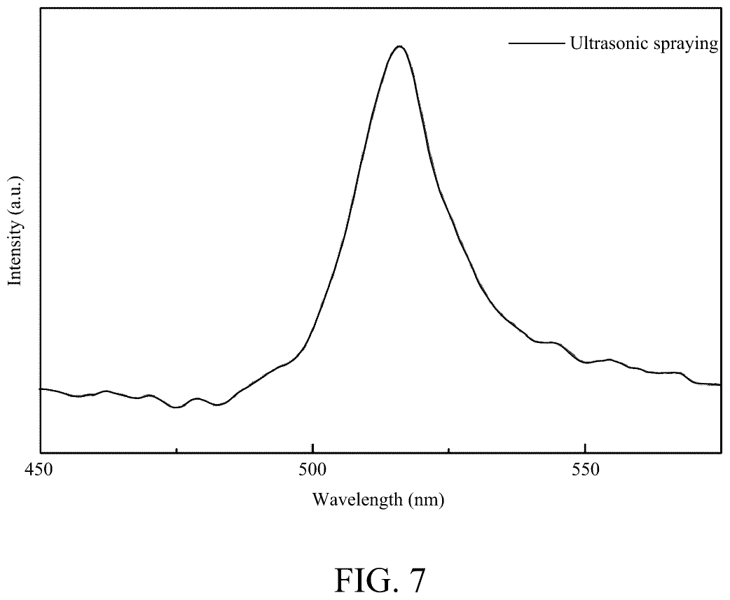

A large-size ultrasonic spraying perovskite thick film was further prepared as in Example 2, wherein the heating temperature of the heating plate beneath the substrate was adjusted to 30° C. and the film had an area of 15*15 cm². The ultrasonic spraying perovskite thick film was irradiated with X-ray and the RL intensity generated was recorded, as shown in FIG. 7. According to FIG. 7, the ultrasonic spraying perovskite thick film exhibited a full width at half maximum (FWHM) up to 21 nm, significantly better than that of the known drop-casting perovskite film, such as the films described in Nano Res. 2022, 15 (3), 2399-2404.

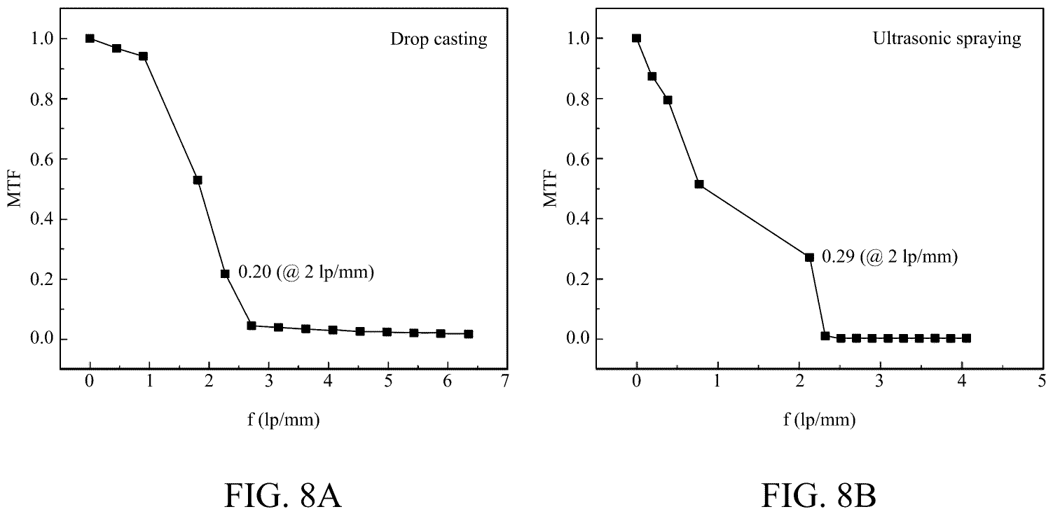

Further, a drop-casting perovskite film and an ultrasonic spraying perovskite thick film were prepared as in Example 2, except that the heating temperature of the heating plate beneath the substrate was adjusted to 30° C. The RL generated by irradiating the films with X-ray was imaged with a CCD camera, and their modulation transfer functions (MTF) were back-calculated to be 0.20 (@ 2 lp/mm) and 0.29 (@ 2 lp/mm), respectively, as shown in FIGS. 8A and 8B. The MTF curve can indicate information on resolution and contrast simultaneously, and therefore the resolution level could be evaluated according to the requirement for a specific application. Based on that the MTF of the drop-casting perovskite film reached only 0.20 while the MTF of the ultrasonic spraying nanosheet perovskite thick film could reach 0.29 at 2 lp/mm, it is concluded that the resolution of the ultrasonic spraying nanosheet perovskite thick film is higher than that of the drop-casting perovskite.

### Example 5—Surfactant

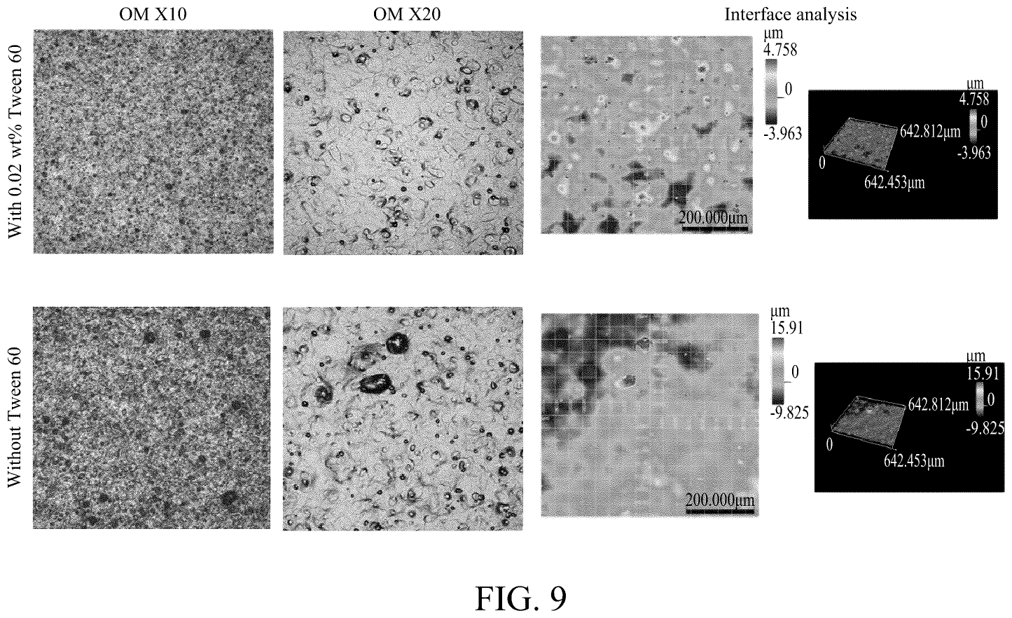

Ultrasonic spraying perovskite thick films were prepared using the preparation method of Example 2, with perovskite precursor solutions without Tween 60 (for comparison) or with 0.02 wt % Tween 60, except that the heating temperature of the heating plate beneath the substrate was adjusted to 30° C. The optical micrograph and interface analysis of each of the films described above were shown in FIG. 9. Based on these results, the addition of 0.02 wt % Tween 60 as a surfactant to the perovskite precursor solution could reduce the surface tension, thereby improving the uniformity of the film.

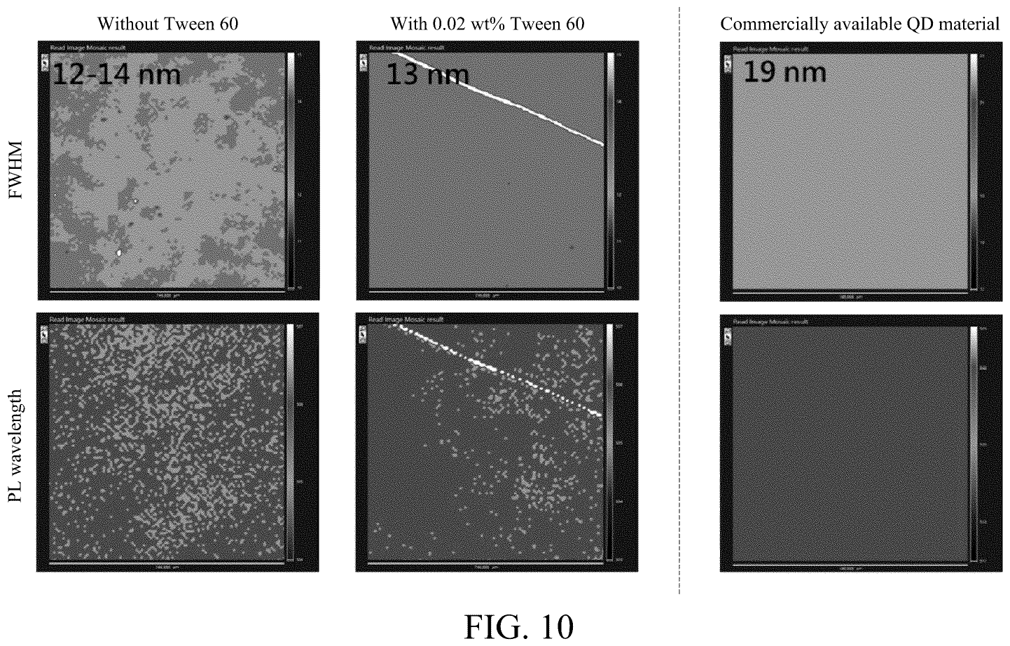

Further, each of the films generated fluorescence upon irradiating with 532 nm laser, and the generated PL wavelength and the full width at half maximum were shown in FIG. 10. The results of a commercially available quantum dot perovskite thick film (purchased from TAIWAN HOPAX CHEMS.MFG.CO., LTD.) were also added to FIG. 10 for comparison. The results showed that the full width at half maximum of the ultrasonic spraying perovskite thick film could reach about 12 nm to 14 nm, better than the full width at half maximum (19 nm) of the commercially available quantum dot perovskite thick film. Also, the addition of Tween 60 as a surfactant during preparation allowed the full width at half maximum at each position in the film to be more uniform.

### Example 6—Surfactant

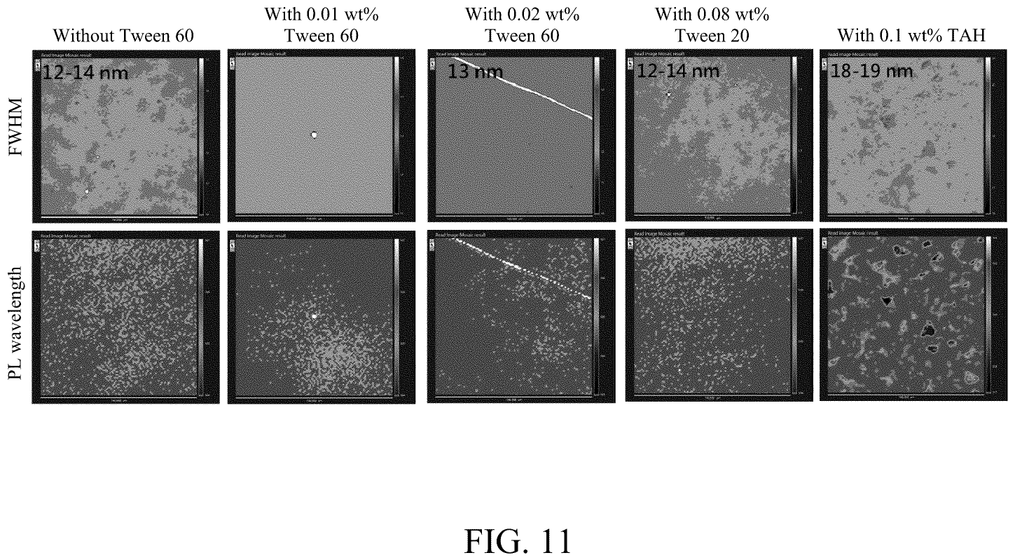

Ultrasonic spraying perovskite thick films were prepared using the preparation method of Example 2, with perovskite precursor solutions without a non-ionic surfactant (for comparison) or with a non-ionic surfactant, including 0.01 wt % Tween 60, 0.02 wt % Tween 60, 0.08 wt % Tween 20, or with a zwitterionic surfactant: 0.1 wt % tetradecyldimethyl(3-sulfopropyl) ammonium hydroxide (TAH) (for comparison), except that the heating temperature of the heating plate beneath the substrate was adjusted to 30° C. The PL wavelength and the full width at half maximum of the fluorescence generated by irradiating each of the films were shown in FIG. 11. Based on these results, the addition of a non-ionic surfactant, such as 0.01 wt % Tween 60, 0.02 wt % Tween 60 and 0.08 wt % Tween 20, allowed the films to have increased uniformity at the full width at half maximum and PL wavelength.

### Example 7—Large-Size Ultrasonic Spraying Perovskite Thick Film

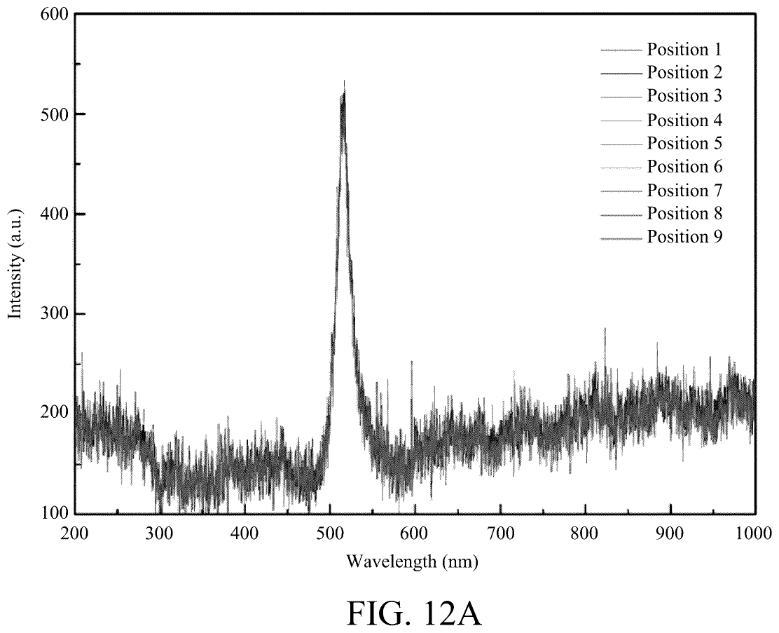

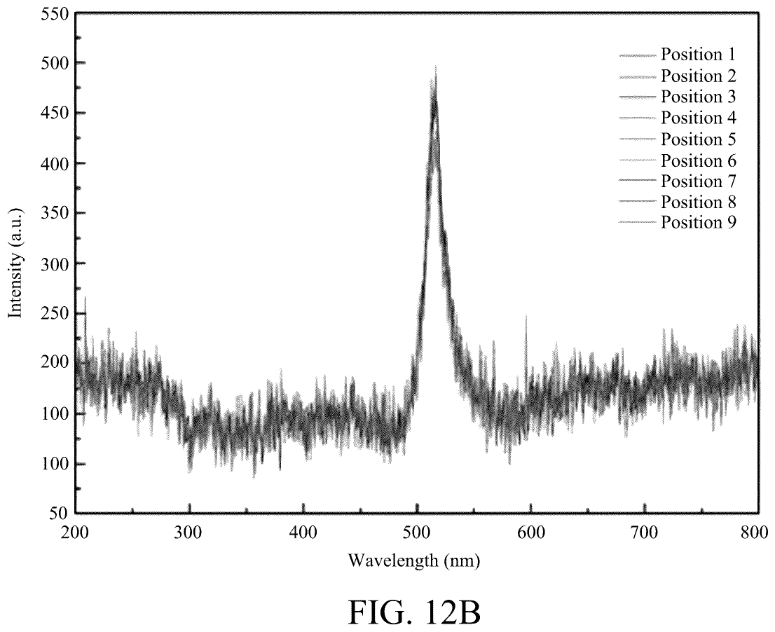

By using the preparation method of Example 2, large-size ultrasonic spraying perovskite thick films were prepared, except that the heating temperature of the heating plate beneath the substrate was adjusted to 30° C. and the hard substrate (e.g., glass) and a PET soft substrate were selected. The films had an area of 15*15 cm². The ultrasonic spraying perovskite thick films on the hard and soft substrates were irradiated with X-ray and the RL generated at 9 uniformly distributed positions in each film were recorded, as shown in FIGS. 12A and 12B. According to FIG. 12A, the ultrasonic spraying perovskite thick film on a hard substrate had an RL wavelength of 520±0.16% nm and an RL intensity of 531±0.39%; and according to FIG. 12B, the ultrasonic spraying perovskite thick film on a soft substrate had an RL wavelength of 520±0.43% nm and an RL intensity of 498±1.31%. These results demonstrated very slight variation (less than 1.5%) in the RL wavelengths and RL intensities of the ultrasonic spraying perovskite thick films, indicating very excellent uniformity.

### Example 8—Ligand

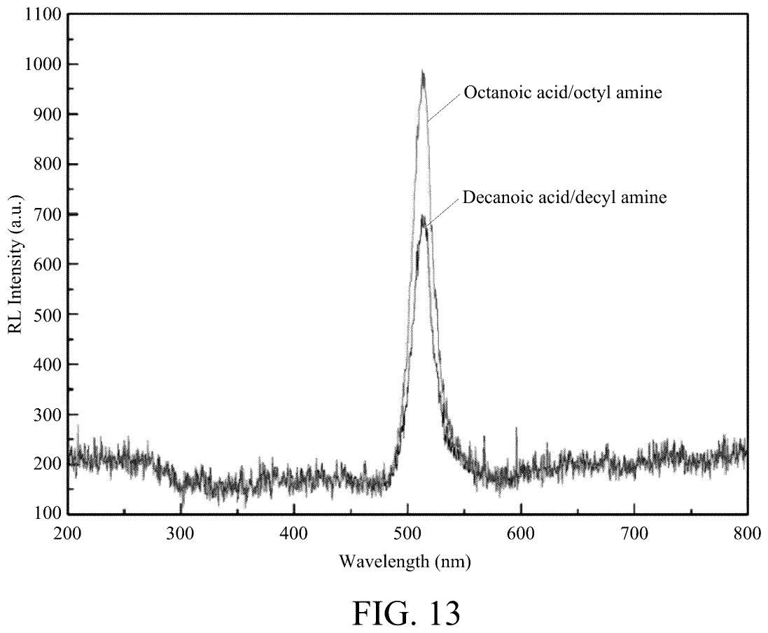

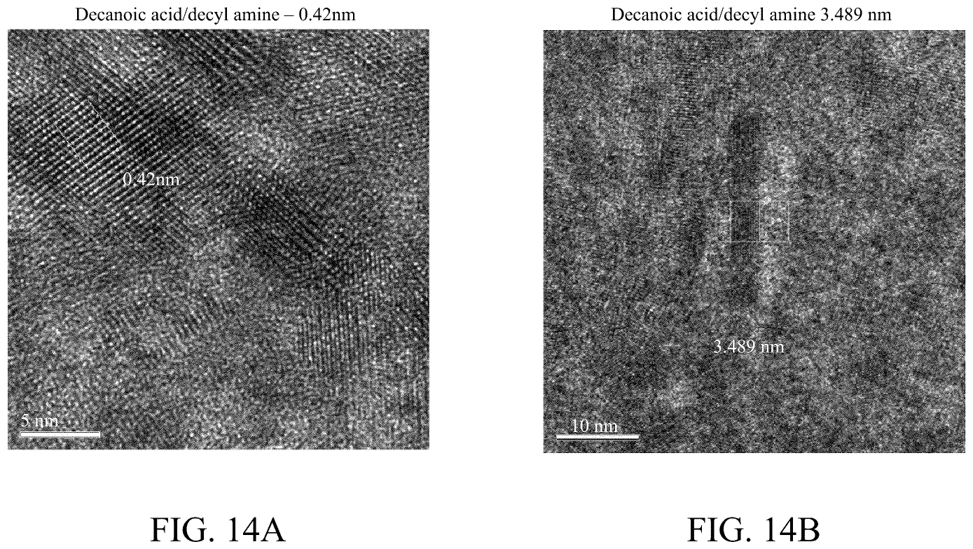

Perovskite precursor solutions were prepared according to the method of Example 2, except that the ligands were changed to butyric acid with n-butyl amine, hexanoic acid with hexyl amine, octanoic acid with octyl amine, or decanoic acid with decyl amine. Ultrasonic spraying perovskite thick films were then prepared as in Example 2, but the heating temperature of the heating plate beneath the substrate was adjusted to 30° C. The structure of each film and whether the detection function of each film works upon X-ray irradiation were observed, and the results were shown in Table 1 below and in FIG. 13, FIG. 14A and FIG. 14B.

TABLE 1

| | Structure of ultrasonic | Whether being |
|---|---|---|
| | spraying perovskite thick | capable of detecting |
| Ligand | film | X-rays or not |
| Butyric acid with | Nanowire | No |
| n-butyl amine | | |
| Hexanoic acid with | Quantum dot + nanosheet | No |
| hexyl amine | | |
| Octanoic acid with | Nanosheet | Yes |
| octyl amine | | |
| Decanoic acid with | Nanosheet | Yes |
| decyl amine | | |

According to Table 1, the perovskite thick film having nanosheet structure (as shown in the TEM images of FIGS. 14A and 14B) was obtained only under the condition of using octanoic acid with octyl amine or decanoic acid with decyl amine as a ligand, and only perovskite thick film having nanosheet structure was capable of generating RL upon X-ray irradiation, as shown in FIG. 13.

### Example 9—Different Perovskites

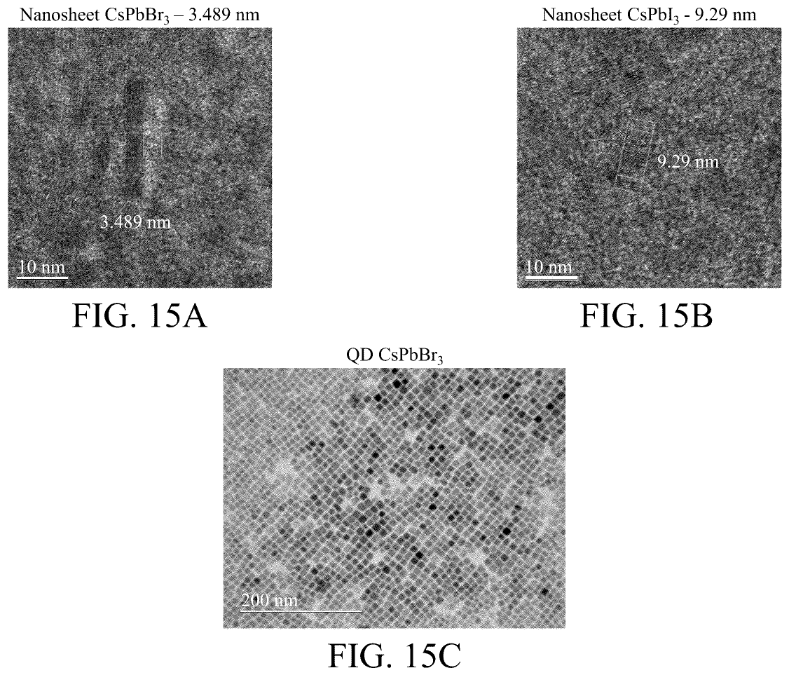

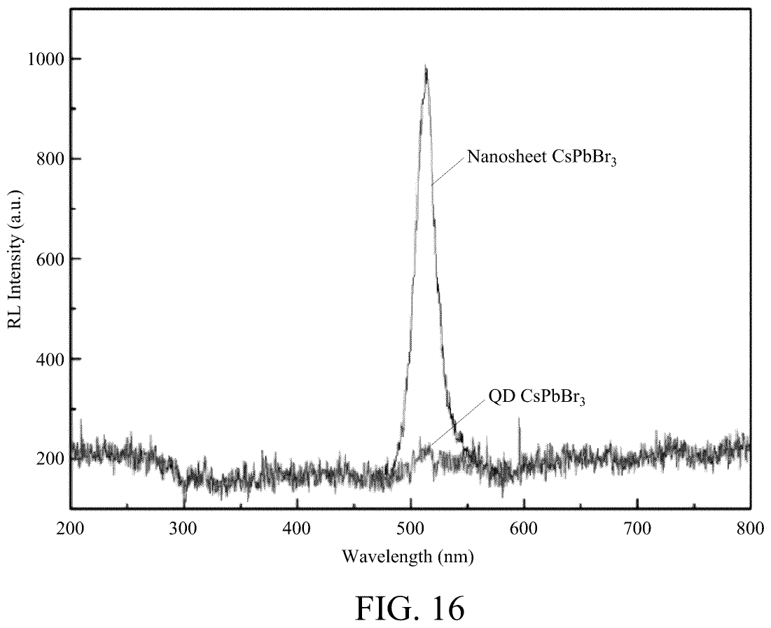

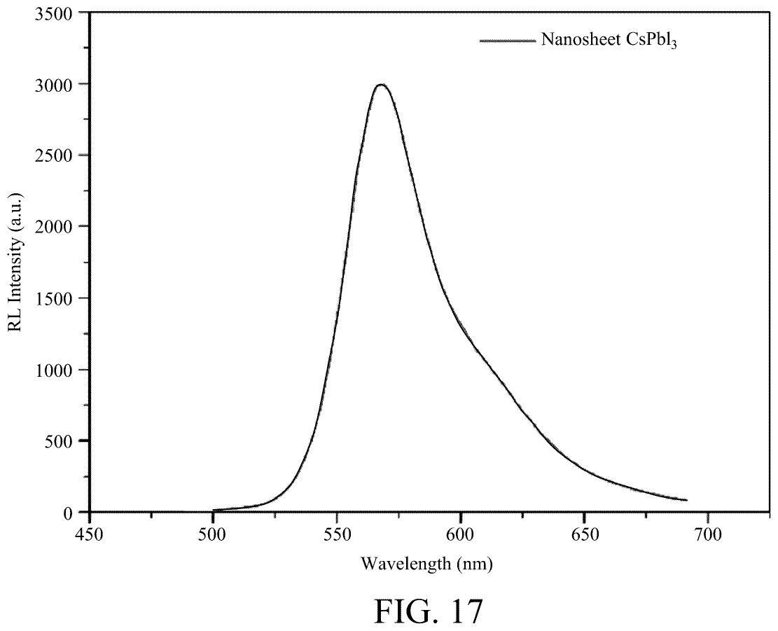

Two 3.2 mM perovskite precursor solutions were prepared according to the method of Example 2, one of which replaced the perovskite precursor salt with 0.3071 g of CsAc and 1.4752 g of PbI₂. Ultrasonic spraying CsPbBr₃ and CsPbI₃ perovskite thick films with a thickness of 60 μm were then prepared, wherein the heating temperature of the heating plate beneath the substrate was adjusted to 30° C. The TEM images of the two films were shown in FIG. 15A and FIG. 15B, respectively. Additionally, the TEM image of a commercially available QD CsPbBr₃ perovskite film (purchased from Quantum Solutions (QS)) was shown in FIG. 15C. Next, each of the films was irradiated with X-ray and the RL generated was recorded. The ultrasonic spraying CsPbBr₃ perovskite thick film and the QD CsPbBr₃ perovskite film had RL intensities as shown in FIG. 16, and the ultrasonic spraying CsPbI₃ perovskite thick film had RL intensity as shown in FIG. 17.

As seen from these results, the ultrasonic spraying perovskite thick film with a thickness of 60 μm could effectively block and absorb X-ray and then emit a visible light. In contrast, the quantum dot perovskite film failed to detect X-ray, possibly due to insufficient thickness.

### Example 10—in Comparison with the Commercially Available QD Perovskite Film

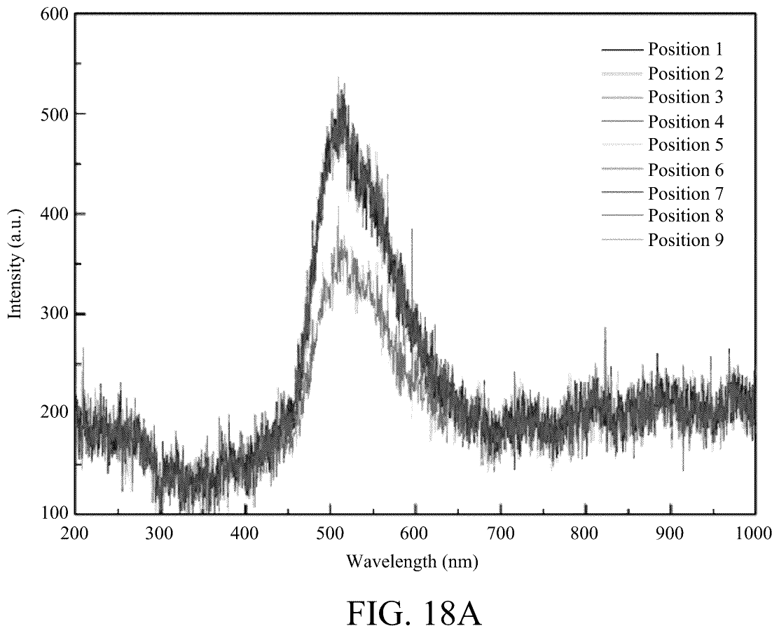

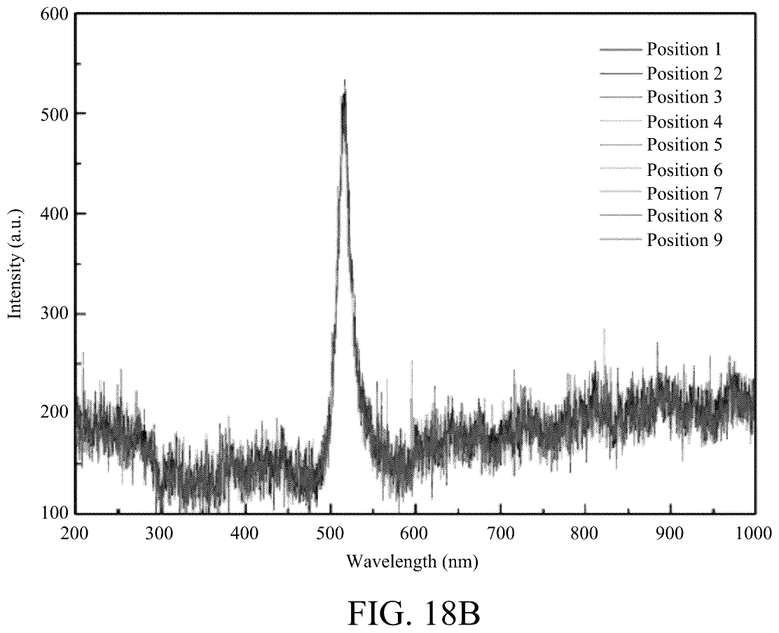

According to the method of Example 7, a large-size ultrasonic spraying perovskite thick film on a hard substrate or soft substrate was prepared, with a film area of 15*15 cm². At 9 evenly distributed positions on the film forming on the soft substrate, the RL generated upon X-ray irradiation was shown in FIG. 18B, wherein the RL wavelength was 520±0.16% nm and the RL intensity was 531±0.39%. On the other hand, at 9 evenly distributed positions on the commercially available quantum dot perovskite film product (having the same film area of 15*15 cm²) from Quantum Solutions (QS), the RL generated upon X-ray irradiation was shown in FIG. 18A, wherein the RL wavelength was 508±1.69% nm, and the RL intensity was 516±10.1%. The results demonstrated that the intensity variation of the large-size sensing film prepared by ultrasonic spraying was 0.39%, better than the intensity variation of the QS product (10.1%); and the wavelength variation of the same was 0.16%, also better than the wavelength variation of the QS product (1.69%).

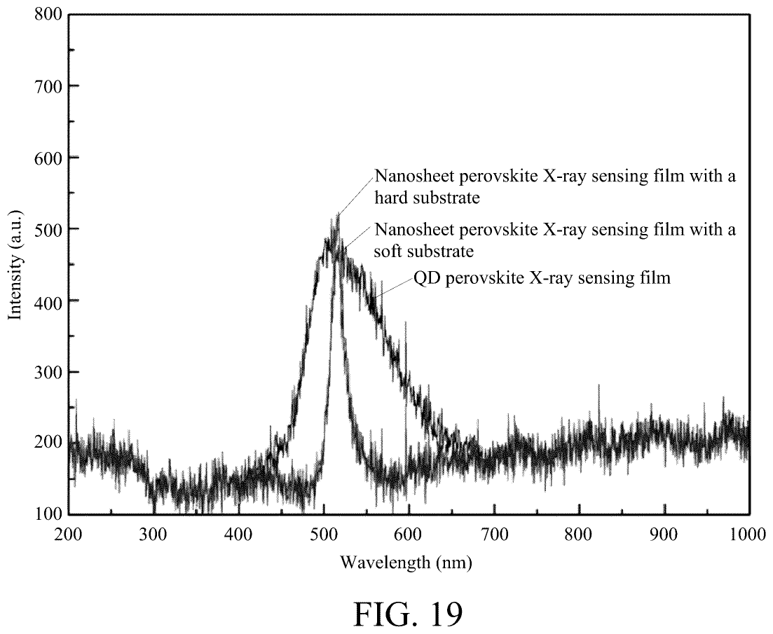

FIG. 19 shows RL of the perovskite thick films on the hard substrate, on the soft substrate, and the quantum dot perovskite film from Quantum Solutions. It can be seen from the results that the ultrasonic spraying perovskite thick films on the hard substrate or soft substrate each had a full width at half maximum of 21 nm, significantly better than a full width at half maximum of the quantum dot perovskite film from Quantum Solutions, which was 112 nm.

### Example 11—Applications of the X-Ray Detector

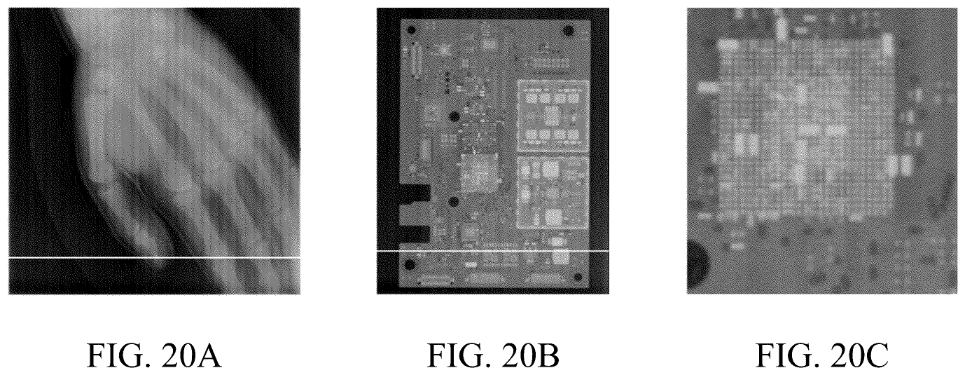

Due to its high sensitivity and resolution, the ultrasonic spraying perovskite thick film of the present disclosure can be used as a part of an X-ray detector for medical detection (as shown in FIG. 20A, the X-ray detector can be used when X-ray was irradiated on a left-hand prosthesis, 80 kVp/160 mA/800 ms), for industrial destructive detection (as shown in FIGS. 20B and 20C, the X-ray detector can be used when X-ray was irradiated on an automotive display circuit board with a trace width of about 100 μm, 80 kVp/160 mA/800 ms), etc.

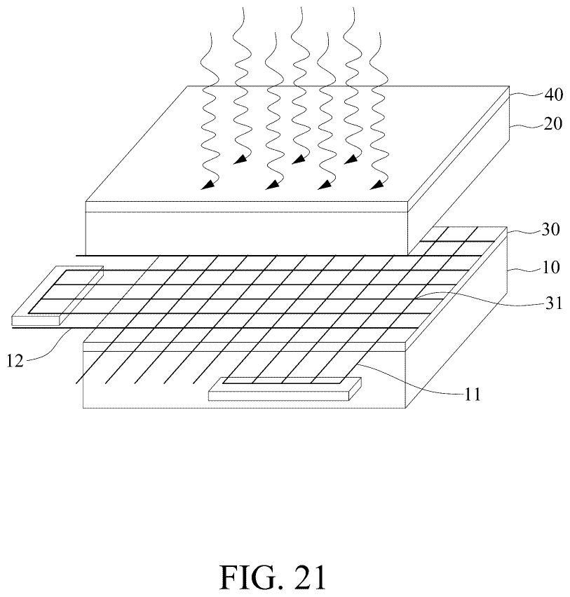

The structural schematic diagram of the X-ray detector of this Example is shown in FIG. 21. The X-ray detector 1 comprises a substrate 10; a pixel array 30 formed on the substrate 10; a perovskite thick film 20 formed on the pixel array 30 (in FIG. 21, the pixel array 30 and the perovskite thick film 20 were shown separately to facilitate illustration of a readout circuit 11 and a photoelectric transducer element 31); and a readout circuit 11 electrically connected to the pixel array 30. Such an X-ray detector converts X-ray to visible light through the perovskite thick film 20, and thus the radiation dose of the X-ray can be obtained by processing and analyzing the visible light. Alternatively, a protecting layer 40 can be formed on the perovskite thick film 20 and is one having both protection and reflection functions, for example, an aluminum film. Additionally, the X-ray detector 1 can also comprise a photoelectric transducer element 31, which can be disposed on the pixel array 30 and be under the control of a control circuit 12 electrically connected thereto. The photoelectric transducer element could convert the visible light generated by the perovskite thick film to an electric signal, and then the electric signal can be further processed through a back-end software for imaging.

1. A radiation detector, comprising:
a substrate;
a pixel array formed on the substrate;
a perovskite thick film having nanosheet structure and formed on the pixel array; and
a readout circuit electrically connected to the pixel array,
wherein the perovskite thick film comprises CsPbBrₘI₃₋ₘ or FAPbBrₘI₃₋ₘ, with 0≤m≤3,
wherein the perovskite thick film comprises a surfactant and a ligand.

2. The radiation detector of claim 1, wherein the surfactant is at least one selected from the group consisting of Tween 20, Tween 40, Tween 60, Tween 65 and Tween 80.

3. The radiation detector of claim 1, wherein the surfactant comprises 0.005 wt % to 0.05 wt % of Tween 60.

4. The radiation detector of claim 1, wherein the ligand is octyl amine with octanoic acid, or decyl amine with decanoic acid.

5. The radiation detector of claim 1, wherein the X-ray diffraction pattern of the perovskite thick film comprises a (100) signal at 3.9±0.3°, a (200) signal at 7.6±0.3° and a (220) signal at 11.4±0.3°.

6. The radiation detector of claim 1, wherein the perovskite thick film has a thickness of 60 μm to 1000 μm.

7. The radiation detector of claim 1, wherein the perovskite thick film has a detecting surface with an area of 200 cm² to 2500 cm².

8. The radiation detector of claim 1, wherein the radiation detector is an X-ray detector, a gamma ray detector, or an X-ray and gamma ray detector.

9. The radiation detector of claim 1, having a radioluminescence wavelength between 520 nm and 600 nm with a full width at half maximum of 25 nm or less, and capable of resolving elements with a width of at least 100 μm.

10. A method of preparing a perovskite thick film, comprising:
a) providing a perovskite precursor solution;
b) spraying the perovskite precursor solution on a substrate to form a perovskite film;
c) repeating the step b) to form a perovskite thick film; and
d) subjecting the perovskite thick film to annealing treatment to obtain a perovskite thick film having a nanosheet structure.

11. The method of claim 10, wherein the perovskite precursor solution in the step a) comprises a perovskite precursor salt, a surfactant, a ligand and a solvent.

12. The method of claim 10, wherein the ligand is a primary amine and a carboxylic acid both having 8 to 12 carbon atoms.

13. The method of claim 10, wherein the ligand is octyl amine with octanoic acid, or decyl amine with decanoic acid.

14. The method of claim 10, wherein the surfactant is present at a weight percentage concentration (wt %) of 0.001 wt % to 0.2 wt %.

15. The method of claim 10, wherein the surfactant is 0.005 wt % to 0.05 wt % of Tween 60.

16. The method of claim 10, wherein in the perovskite precursor solution, the volume ratio of the surfactant:the ligand:the solvent is 0.8-1.2:0.8-1.2:1.

17. The method of claim 10, wherein in the perovskite thick film comprises CsPbBrₘI₃₋ₘ or FAPbBrₘI₃₋ₘ, with 0≤m≤3.

18. The method of claim 10, wherein the spraying used in the step b) is ultrasonic spraying, with an ultrasonic power of 1 W to 3 W, an ejection rate of 0.1 mL/min to 3 mL/min and a nozzle moving speed of 1 mm/s to 50 mm/s.

19. The method of claim 10, further comprising a step e): heating the perovskite film or the perovskite thick film at a temperature of 25° C. to 200° C.

20. The method of claim 10, further comprising, between the step a) and the step b), a step f): subjecting the perovskite precursor solution to a vibration pretreatment at a vibration power of 100 W to 200 W for 1 to 10 minutes.
